(19) United States
(12) Patent Application Publication
(10) Pub. No.: US 2006/0203595 A1
(43) Pub. Date: Sep. 14, 2006

(54) Multiple memory device management

(75) Inventor: Van D. Nguyen, San Jose, CA (US)

Correspondence Address: LEFFERT JAY & POLGLAZE, P.A., P.O. BOX 581009, MINNEAPOLIS, MN, 55458-1009, US

(73) Assignee: Micron Technology, Inc.

(21) Appl. No.: 11/436,803

(22) Filed: May 18, 2006

Related U.S. Application Data
(63) Continuation of application No. 10/624,421, filed on Jul. 22, 2003.

(51) Int. Cl. G11C 8/00

(52) U.S. Cl. 365/230.01

(57) ABSTRACT

Multiple memory devices can be managed as though they were one memory device. A memory device that has a logical memory address map can be replaced with multiple memory devices that each has an address range that is a subset of the logical memory address map. When one of the multiple memory devices is addressed in the logical memory address map, a corresponding physical address is generated from the logical address. The physical address is used to generate a chip select signal for that particular memory device.

### RELATED APPLICATIONS

This application is a continuation of U.S. patent application Ser. No. 10/624,421 (pending), filed Jul. 22, 2003 and titled “MULTIPLE FLASH MEMORY DEVICE MANAGEMENT,” which is commonly assigned and incorporated by reference in its entirety herein.

### BACKGROUND OF THE INVENTION

I. Field of the Invention

The present invention relates generally to memory devices and particularly to flash memory devices.

II. Description of the Related Art

Flash memory devices have developed into a popular source of non-volatile memory for a wide range of electronic applications. Flash memory devices typically use a one-transistor memory cell that allows for high memory densities, high reliability, and low power consumption. Common uses for flash memory include portable computers, personal digital assistants PDAs), digital cameras, and cellular telephones. Program code, system data such as a basic input/output system BIOS), and other firmware can typically be stored in flash memory devices. Most electronic devices are designed with a single flash memory device.

Flash memory devices are manufactured in various memory densities. For example, flash memory may be manufactured in 16 megabyte MB), 32 MB, and 64 MB as well as other densities. The availability of each type of flash memory density, however, may vary depending on market conditions. One type of memory may be easy to obtain while another may be in demand and difficult to buy.

A problem exists when an electronic device is designed to accept a flash memory device, having a particular memory density, that subsequently becomes difficult to obtain or even unavailable. The operating system of the device has been designed to access only a single range of addresses in order to access that particular flash memory device. There is a resulting need in the art for a way to replace a single flash memory device with multiple memory devices while enabling the operating system or other programs to access the new devices in a seamless fashion.

### BRIEF DESCRIPTION OF THE DRAWINGS

FIG. 1 shows a block diagram of one embodiment of a memory system of the present invention.

FIG. 2 shows one embodiment of a table of logical addresses and corresponding physical addresses.

FIG. 3 shows one embodiment of a table entry in accordance with the present invention.

FIG. 4 shows a flowchart of one embodiment of a memory management method of the present invention.

FIG. 5 shows an alternate embodiment of a memory system of the present invention.

### DETAILED DESCRIPTION

The embodiments of the present invention enable a single flash memory device to be replaced with multiple flash memory devices without changing the system's memory map. The embodiments of the present invention may be implemented in a system that is initially designed with a single flash memory that is replaced due to unavailability of the memory or for cost reasons. The single flash memory can be replaced by two or more smaller memories that can be addressed by the operating system or applications in a seamless fashion over non-contiguous physical address space.

While the subsequent discussion of the embodiments of the present invention refers to flash memory, any type of memory device that has similar characteristics may be used. For example non-volatile RAM NOVRAM or electrically erasable programmable read only memory EEPROM may be used.

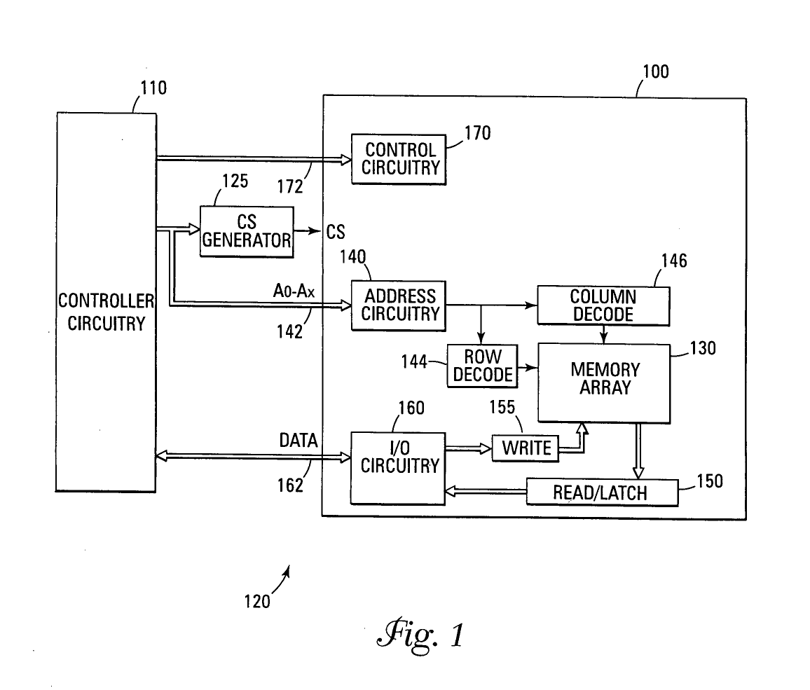

FIG. 1 is a functional block diagram of a memory device 100 of one embodiment of the present invention that is coupled to a controller circuit 110. The controller circuit 110 may be a microprocessor, a processor, or some other type of controlling circuitry. The memory device 100 and the controller 110 form part of an electronic system 120. The memory device 100 has been simplified to focus on features of the memory that are helpful in understanding the present invention.

The memory device includes an array of memory cells 130. The memory cells are non-volatile floating-gate memory cells and the memory array 130 is arranged in banks of rows and columns.

An address buffer circuit 140 is provided to latch address signals provided on address input connections A0-Ax 142. Address signals are received and decoded by a row decoder 144 and a column decoder 146 to access the memory array 130. It will be appreciated by those skilled in the art, with the benefit of the present description, that the number of address input connections depends on the density and architecture of the memory array 130. That is, the number of addresses increases with both increased memory cell counts and increased bank and block counts.

The memory device 100 reads data in the memory array 130 by sensing voltage or current changes in the memory array columns using sense/latch circuitry 150. The sense/latch circuitry, in one embodiment, is coupled to read and latch a row of data from the memory array 130. Data input and output buffer circuitry 160 is included for bi-directional data communication over a plurality of data connections 162 with the controller 110. Write circuitry 155 is provided to write data to the memory array.

Command control circuit 170 decodes signals provided on control connections 172 from the processor 110. These signals are used to control the operations on the memory array 130), including data read, data write, and erase operations.

Chip select generation circuitry 125 generates the chip select signals for the memory device 100. This circuitry 125 uses the address connections 142 from the controller 110 to generate the appropriate chip select signal depending on the address present on the address connections 142.

The flash memory device illustrated in FIG. 1 has been simplified to facilitate a basic understanding of the features of the memory. A more detailed understanding of internal circuitry and functions of flash memories are known to those skilled in the art.

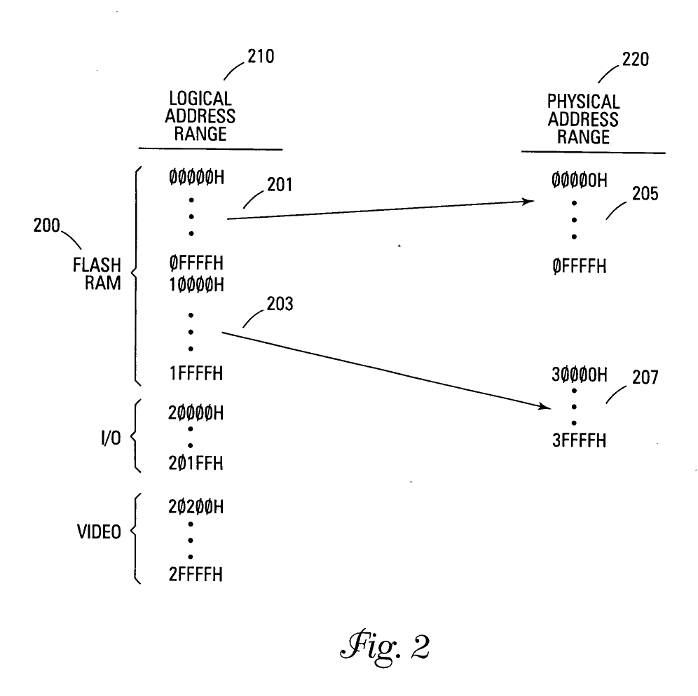

FIG. 2 illustrates one embodiment of a table of logical addresses and their corresponding physical addresses. This figure is for illustration purposes only and does not limit the present invention to any memory address range or ranges.

An electronic system, such as the embodiment of FIG. 1, is designed with a memory device logical address map 210 of all of the memory and input/output I/O of the system. This map is used by the operating system and/or applications running on the system when it is desired to access a particular memory or I/O. For example, if the electronic system is a digital camera and a picture is being written to flash RAM, the system would write to a memory address in the range of 00000H to 1FFFFH to store the picture.

The logical address range 210 of FIG. 2 has a flash memory address range 200 of 128 MB. For purposes of illustration, the system might also have an address range from 20000H to 201FFH for I/O and 20200H to 2FFFFH for video memory.

If the electronic system has a single 128 MB flash RAM device, only a single chip select is required to access the device. In this case, any program or operating system that generates an address in the range of 00000H to 1FFFFH would generate a chip select for the 128 MB flash RAM.

However, if the electronic system has two 64 MB flash RAM devices, its physical address range 220 might be different than the logical address range 210. The electronic system might split up the single flash memory address range 200 into two logical address sub-ranges 201 and 203 for the two flash RAMs. Each logical address sub-range 201 and 203 could then be mapped to different physical address ranges 205 and 207 respectively.

In such an embodiment, the system would have to generate two separate chip selects, one for each physical address range 205 and 207. In the embodiment of FIG. 2, the two physical address ranges are 00000H to 0FFFFH for the first 64 MB logical address range 201 and 30000H to 3FFFFH for the second 64 MB logical address range 203. The physical address ranges 205 and 207 for the flash memory may be contiguous or non-contiguous. FIG. 2 illustrates a non-contiguous embodiment.

The embodiments of the present invention are not limited to two separate physical address ranges to replace the single logical address range. An alternate embodiment may use four 32 MB memory devices in place of the 128 MB device. This would require four physical address ranges. Still other alternate embodiments may be designed with a flash memory other than 128 MB. For example, the electronic system may have a logical address range of 64 MB.

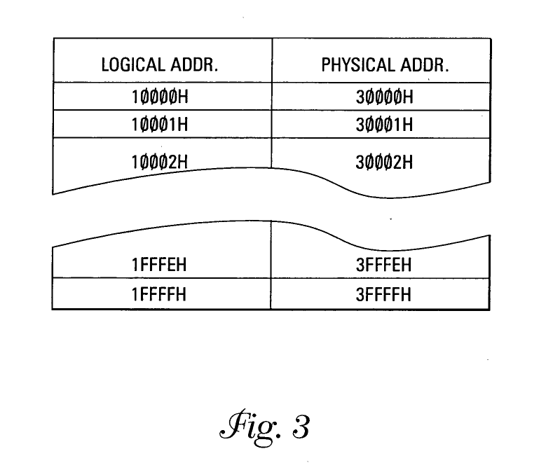

FIG. 3 illustrates one embodiment of memory map look-up table entries in accordance with the present invention. In this embodiment, the logical address 10000H maps to 30000H and 10001H maps to 30001H. This continues for the range of the logical addresses assigned to the flash memory. The operating system or other applications access a table such as is illustrated in FIG. 3 in order to determine the physical memory location of the memory to which the application wishes to write.

For example, if the operating system receives a request to write data to logical memory address 10002H, it checks the table to determine that logical memory address maps to physical memory address 30002H. The controller circuit then outputs that physical address on the address lines in order to generate the appropriate chip select for the appropriate memory device.

A memory map look-up table is only one embodiment for generating a corresponding physical address for a logical address. In an alternate embodiment, the controller circuit or a management device generates the physical address by adding a predetermined address offset to the logical address.

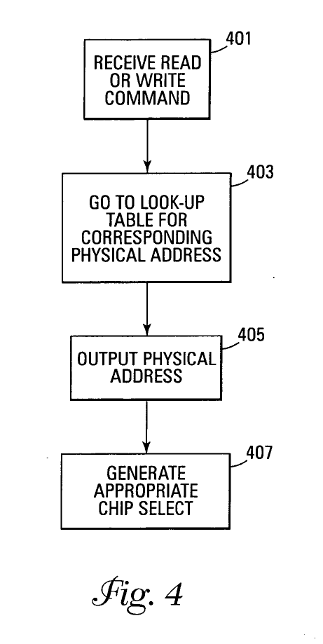

FIG. 4 illustrates a flowchart of one embodiment of a flash memory management method of the present invention. The controller circuit receives a read or write command from an operating system or other software application 401. The read or write command contains a logical address from or to which the application desires to read or write data. The controller accesses a look-up table in memory to find the corresponding physical address 403 for that particular logical address. The look-up table may be stored in RAM, ROM, flash RAM, or any other memory accessible by the controller.

The controller can then output the physical address 405 to the chip select generation circuitry over the address lines. The chip select generation circuitry uses the addresses from the controller in order to generate 407 the various chip select signals. For example, if the address that is output is in the first 64 MB physical address range of FIG. 2, a first chip select signal is generated. If the address is in the second 64 MB physical address range, a second chip select signal is generated.

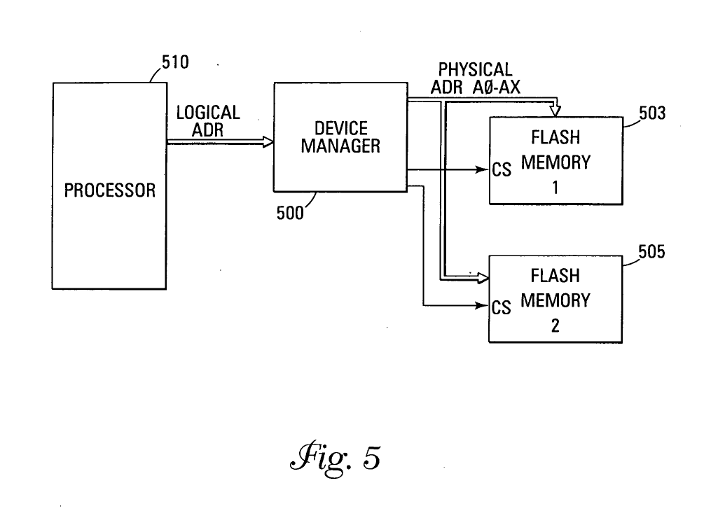

The above-described embodiment describes a controller and chip select circuitry to generate the addresses and chip select signals. An alternate embodiment of this system is illustrated in FIG. 5. The system of FIG. 5 uses a device manager 500 that, in one embodiment, contains the look-up table functions of the controller circuitry and the chip select signal generation function of the embodiment of FIG. 1.

In one embodiment, the device manager is a software module that is stored in memory, such as one of the multiple flash memory devices 503 and 505. In another embodiment, the device manager is a hardware device such as an application specific integrated circuit ASIC or a field programmable gate array FPGA.

The device manager 500 receives the logical addresses from the processor 510 that is executing an operating system or other software application. The device manager 500 then accesses a look-up table, stored in the device manager 500 or some memory device, in order to generate the appropriate physical address and chip select signals for the multiple flash memories 503 and 505.

In summary, the embodiments of the present invention enable multiple memory devices at non-contiguous physical addresses to be addressed as if they were a single device. With the embodiments of the present invention, multiple smaller memory devices that are more readily available or less expensive can be substituted for one larger memory device. This is accomplished without changing the logical memory map of the electronic system.

Numerous modifications and variations of the present invention are possible in light of the above teachings. It is therefore to be understood that within the scope of the appended claims, the invention may be practiced otherwise than as specifically described herein.

What is claimed is:

1. A memory device comprising:
a plurality of memory arrays, each array having a range of physical addresses; and
control circuitry coupled to the plurality of memory arrays and controlling operation of the memory device, the control circuitry adapted to execute a method for managing the plurality of memory arrays over the plurality of ranges of physical addresses including receiving a first logical address, determining a corresponding first physical address from one of the plurality of ranges of physical addresses, and generating a select signal in response to the first physical address.

2. The device of claim 1 wherein the plurality of ranges of physical addresses are non-contiguous.

3. The device of claim 1 wherein the plurality of ranges of physical addresses is substantially equivalent to the plurality of ranges of logical addresses.

4. The device of claim 1 wherein the plurality of memory arrays are flash memory arrays.

5. The device of claim 1 wherein the plurality of ranges of logical addresses is contiguous and the corresponding range of physical addresses is non-contiguous and comprised of a plurality of physical address sub-ranges.

6. The device of claim 5 wherein a select signal is generated for each physical address sub-range.

7. A flash memory device comprising:
a plurality of flash memory arrays, each array having a range of physical addresses; and
a device manager for managing the plurality of flash memory arrays over a range of logical addresses, the device manager adapted to receive a first logical address from the range of logical addresses, determine a corresponding physical address from one of the plurality of ranges of physical addresses, and generate a select signal for one of the plurality of flash memory arrays in response to the corresponding physical address.

8. The device of claim 7 wherein the first logical address is received in a command from a controller circuit executing an application in which the first logical address is read from memory with the command.

9. The device of claim 8 wherein the command is received by the device manager from the controller circuit.

10. The device of claim 7 wherein the device manager is stored in the flash memory device.

11. A method for managing a plurality of flash memory devices over a range of logical addresses, the method comprising:
receiving a first logical address from the range of logical addresses in response to execution of an application;
determining a first physical address, from a range physical addresses comprising a plurality of non-contiguous sub-ranges, that corresponds to the first logical address;
outputting the first physical address to select signal generation circuitry; and
the select signal generation circuitry generating a select signal in response to the first physical address.

12. The method of claim 11 wherein each of the plurality of non-contiguous sub-ranges is substantially equal to a logical address range of a flash memory device of the multiple flash memory devices.

13. A memory system having a logical address map comprising a flash memory logical address range for a memory device, the system comprising:
a plurality of flash memory arrays having a combined physical address range substantially equivalent to the flash memory logical address range;
a controller circuit coupled to the plurality of memory arrays, the controller circuit adapted to generate a first physical address in the combined physical address range in response to a first logical address received from an executing software application; and
a select signal generation circuit coupled to the controller circuit and the plurality of memory arrays, the select signal generation circuit transmitting a select signal to one of the plurality of memory arrays in response to the first physical address.

14. The system of claim 13 wherein the controller circuit is coupled to the plurality of flash memory arrays through a plurality of address lines.

15. The system of claim 13 wherein the controller circuit generates the first physical address in response to a look-up table entry comprising the first logical address and the first physical address.

16. The system of claim 13 wherein the controller circuit generates the first physical address in response to adding an address offset to the first logical address.

17. A memory system having a logical address map comprising a flash memory logical address range for a memory device, the system comprising:
a processor for executing a software application thereby generating a first logical address;
a plurality of flash memory devices having a combined physical address range substantially equivalent in size to the flash memory logical address range, the plurality of flash memory devices coupled to the processor over address lines;
a device manager adapted to generate a first physical address from the combined physical address range in response to the first logical address, and generate a select signal to one of the plurality of memory devices in response to the first physical address.

18. The system of claim 17 wherein the controller function uses a look-up table stored in memory to generate the physical address in response to the first logical address.

19. The system of claim 17 wherein the controller function adds an address offset to the first logical address to generate the physical address.

20. In a memory system that is controlled by a processor, a method for managing a plurality of flash memory devices over a range of logical addresses, the method comprising:
executing a software application;
generating a first logical address within the range of logical addresses in response to the execution of the application;
generating a first physical address, from a range physical addresses comprising a plurality of non-contiguous address sub-ranges, corresponding to the first logical address; and
transmitting a select signal, generated in response to the first physical address, to a first flash memory device of a plurality of flash memory devices.
